(19) United States
(12) Patent Application Publication
(10) Pub. No.: US 2013/0038338 A1
(43) Pub. Date: Feb. 14, 2013

(54) Parasitic Capacitive Canceling in a Sensor Interface

(71) Applicants: Lauri Ilmari Lipasti, Helsinki (FI); Jukka Sakari Riihiaho, Vantaa (FI)

(72) Inventors: Lauri Ilmari Lipasti, Helsinki (FI); Jukka Sakari Riihiaho, Vantaa (FI)

(21) Appl. No.: 13/206,079

(22) Filed: Aug. 9, 2011

(51) Int. Cl. G01R 27/26

(52) U.S. Cl. 324/658

(57) ABSTRACT

In one embodiment, a method includes communicating a first voltage to a drive line of a touch sensor; setting a sense line of the touch sensor to a predetermined voltage; and communicating a second voltage to the drive line. A resulting transition at the drive line from the first voltage to the second voltage causes an amount of charge accumulated on the sense line to be communicated to an integrator. The method also includes, at the integrator, integrating the amount of charge communicated from the sense line to convert the amount of charge to an output voltage. The method also includes restoring the sense line to the predetermined voltage.

### TECHNICAL FIELD

This disclosure generally relates to measuring capacitance.

### BACKGROUND

An array of conductive drive and sense electrodes may form a mutual-capacitance touch screen having one or more capacitive nodes. An intersection of a drive electrode and a sense electrodes in the array may form a capacitive node. At the intersection, the drive and sense electrodes may come near each other, but they do not make electrical contact with each other. Instead, the sense electrode is capacitively coupled to the drive electrode. A pulsed or alternating voltage applied to the drive electrode may induce a charge on the sense electrode, and the amount of charge induced may be susceptible to external influence (such as a touch by or the proximity of an object). When an object touches or comes within proximity of the drive and sense electrodes, a change in capacitance may occur at that capacitive node. By measuring changes in capacitance throughout the array, the controller may determine the position of the touch or proximity on the touch sensor.

An array of conductive electrodes of a single type (e.g. drive) may form a self-capacitance touch screen. Each of the conductive electrodes in the array may form a capacitive node, and, when an object touches or comes within proximity of the electrode, a change in self-capacitance may occur at that capacitive node and a controller may measure the change in capacitance as a change in voltage or a change in the amount of charge needed to raise the voltage by a pre-determined amount. As with a mutual-capacitance touch screen, by measuring changes in voltage throughout the array, the controller may determine the position of the touch or proximity on the touch sensor.

In a touch-sensitive display application, a touch screen may enable a user to interact directly with what is displayed on a display underneath the touch screen, rather than indirectly with a mouse or touchpad. A touch screen may be attached to or provided as part of, for example, a desktop computer, laptop computer, tablet computer, personal digital assistant (PDA), smartphone, satellite navigation device, portable media player, portable game console, kiosk computer, point-of-sale device, or other suitable device. A control panel on a household or other appliance may include a touch screen.

### BRIEF DESCRIPTION OF THE DRAWINGS

FIG. 1 illustrates an example system for canceling parasitic capacitance in a sensor interface.

FIG. 2 illustrates example waveforms for the example system of FIG. 1.

FIG. 3 illustrates an example use of the example system of FIG. 1.

FIG. 4 illustrates an example method for canceling parasitic capacitance in a sensor interface.

### DESCRIPTION OF EXAMPLE EMBODIMENTS

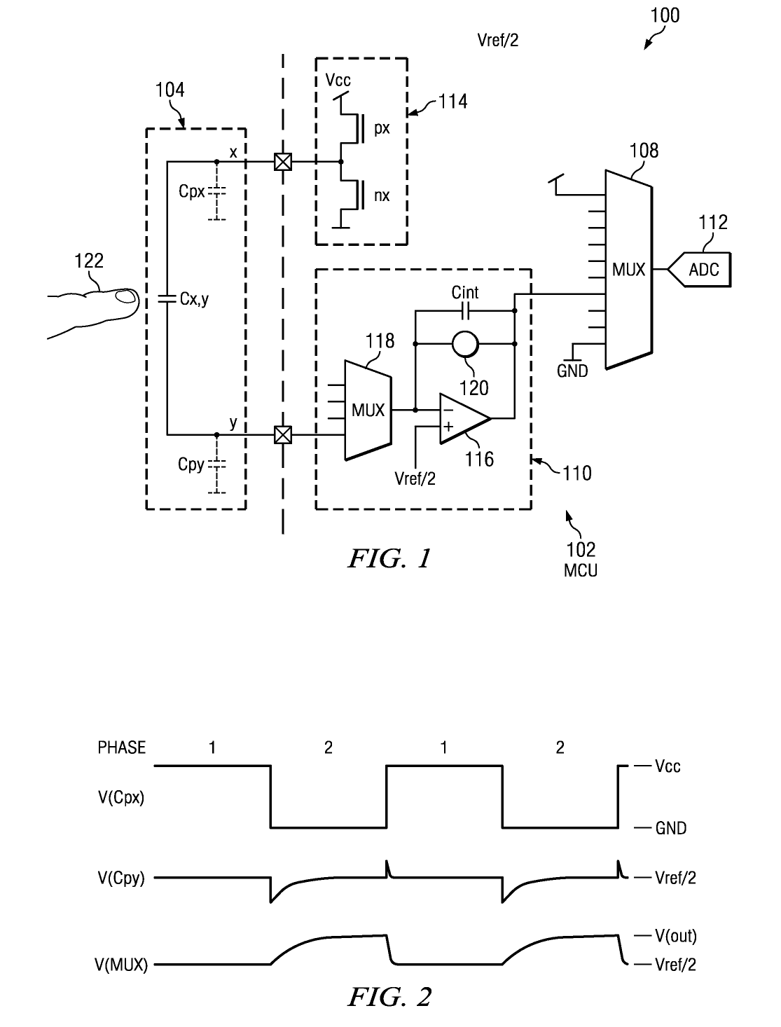

FIG. 1 illustrates an example system 100 for canceling parasitic capacitance in a sensor interface. In the example of FIG. 1, system 100 includes a microcontroller (MCU) 102 and a touch sensor 104. Microcontroller 102 includes a multiplexer 108, a parasitic-canceling circuit 110, a driver 114, and an analog-to-digital converter (ADC) 112 or any other voltage-level detector. Parasitic-canceling circuit 110 includes an operational amplifier 116 and a multiplexer 118. Coupled to a negative input terminal of operational amplifier 116 is an integration capacitor Cᵢₙₜ in parallel with a switch 120. A positive input terminal of operational amplifier 116 is coupled to a voltage, e.g., half a reference voltage V_{ref}/2. The parallel combination of integration capacitor Cᵢₙₜ and switch 120 forms a feedback loop with operational amplifier 116. Microcontroller 102 may be coupled to a touch sensor 104 through one or more sense lines Y.

In particular embodiments, touch sensor 104 may be a mutual-capacitance touch sensor that includes an array of drive electrodes and sense electrodes coupled to one of corresponding drive lines X and sense lines Y, respectively. Each intersection of a drive electrode and sense electrode forms a capacitive node C_{x,y}. In particular embodiments, touch sensor 104 may be a self-capacitance touch sensor 104. Self-capacitance touch sensor 104 includes one or more electrodes coupled to an associated sense line Y. Self-capacitance touch sensor 104 detects a presence of an object through an interaction between the object and an electric field generated by one or more electrodes of self-capacitance touch sensor 104. In particular embodiments, the capacitance of capacitive nodes C_{x,y} is significantly smaller than a value of the parasitic capacitances C_{py} and Cₚₓ associated with sense lines Y and drive lines X, shown schematically in FIG. 1. Although this disclosure describes a particular microcontroller having particular functionality with respect to particular touch sensors, this disclosure contemplates any suitable microcontroller having any suitable functionality with respect to any suitable application without touch sensors.

Microcontroller 102 may detect and process the change in capacitance to determine the presence and location of a touch or proximity input. Microcontroller 102 may be one or more integrated circuits (ICs), such as for example general-purpose microprocessors, microcontrollers, programmable logic devices or arrays, application-specific ICs (ASICs). Although this disclosure describes and illustrates a particular microcontroller in system 100, this disclosure contemplates any suitable microcontroller in system 100.

Driver 114 transmits a drive signal to one or more drive electrodes through drive lines X. The drive signal induces charge on the associated sense electrode through capacitive nodes C_{x,y}. As an example and not by way of limitation, driver 114 may be implemented as an inverter with p-type metal-oxide semiconductor (PMOS) transistor pₓ and n-type metal-oxide semiconductor (NMOS) transistor nₓ. Driver 114 may also be realized through other circuits, such as an analog buffer providing predetermined voltage levels. Interaction between an object 122 and touch sensor 104 may affect an amount of charge induced on one or more sense electrodes. The induced charge is sensed as a change in capacitance by microcontroller 102.

In particular embodiments, the change of capacitance between the free space capacitance of capacitive nodes C_{x,y} (“non-touch”) compared with the capacitance resulting from interaction with an object in proximity to touch sensor 104 (“touch”) is much smaller than a value of the parasitic capacitances C_{py} and Cₚₓ. The value of parasitic capacitances C_{py} and Cₚₓ may vary depending on temperature and from receiving interference from other circuits. For at least these reasons, determining a change of capacitance associated with a “touch” compared to a change of capacitance associated with a “non-touch” in touch sensor 104 may be problematic due to parasitic capacitances C_{py} and Cₚₓ. Although this disclosure describes and illustrates a particular arrangement of particular components for system 100, this disclosure contemplates any suitable arrangement of any suitable components for system 100.

Multiplexer 118 of parasitic-canceling circuit 110 selects one of sense lines Y coupled to input multiplexer 118. Multiplexer 118 communicates the voltage across capacitive node C_{x,y} coupled to selected one of sense lines Y to operational amplifier 116. Multiplexer 118 selects another of one of sense lines Y after measuring the voltage of selected one of sense lines Y. In particular embodiments, multiplexer 118 selects the voltage on each sense line Y in accordance with a predetermined sequence.

Parasitic-canceling circuit 110 has two modes of operation. In the first mode, switch 120 is closed, bypassing integration capacitor Cᵢₙₜ. Bypassing integration capacitor Cᵢₙₜ turns operational amplifier 116 into a unity gain amplifier, which drives the voltage at a negative input terminal of the operational amplifier 116, as well as the output of one selected input of multiplexer 118, to the voltage of a positive terminal of the operational amplifier 116, e.g., half a reference voltage (V_{ref}/2). In addition, closing the feedback loop of operational amplifier 116 removes charge from the integration capacitor Cᵢₙₜ.

In the second mode, switch 120 coupled to the feedback loop of operational amplifier 116 is opened, forming an integrator using integration capacitor Cᵢₙₜ and operational amplifier 116. Opening switch 120 couples integration capacitor Cᵢₙₜ between the negative input terminal and the output terminal of the integrator. The integrator generates a voltage that is a function of the amount of charge transferred from the selected one of sense lines Y. In particular embodiments, the voltage from the amount of charge may be transmitted to ADC 112 for conversion to a digital representation of the voltage.

FIG. 2 illustrates example waveforms for the example system of FIG. 1. In the example of FIG. 2, example waveforms include the voltage of the drive lines V(Cpₓ), the voltage of the selected one of sense lines V(Cp_{y}), and the output voltage of the parasitic-canceling circuit V(MUX) on the selected input of multiplexer 108. The behavior of each waveform V(Cpₓ), V(Cp_{y}), and V(MUX) may be described with respect to two distinct phases.

During Phase 1, drive signal V(Cpₓ) applies a supply voltage, i.e., Vcc, to the drive lines. As discussed above, drive signal V(Cpₓ) transmitted through the drive lines induces charge on the sense electrode of the capacitive nodes. At approximately the same time, the switch coupled to the operational amplifier is closed. Closing the feedback loop of the operational amplifier turns the operational amplifier into a unity gain amplifier, and drives the voltage at the negative input terminal of the operational amplifier, as well as the output of the multiplexer V(MUX) 108, to the voltage of a positive input terminal of the operational amplifier, V_{ref}/2. In addition, the voltage of the positive terminal of the operational amplifier is communicated to selected one of sense lines Y through the multiplexer of the parasitic-canceling circuit, as seen by voltage V(Cp_{y}).

During Phase 2, the switch coupled to the feedback loop of the operational amplifier is opened. As discussed above, opening the switch couples the integration capacitor between the negative input terminal and the output terminal of the operational amplifier. At approximately the same time, drive signal V(Cpₓ) applies a low voltage, for example ground, to the drive lines of the capacitive nodes. Charge induced on the sense electrode of the capacitive nodes during Phase 1 is transferred to the integration capacitor coupled to the operational amplifier. The transfer of charge may be initially seen as drop in the voltage of the sense line V(Cp_{y}) and as an increase of the voltage at the output of the multiplexer V(MUX) 108. Negative feedback from the transfer of charge causes the integrator circuit to compensate by providing a current to the sense line until the voltage of the sense line returns to V_{ref}/2. As a result the charge induced on the selected sense electrode is integrated by the integration capacitor, where the integrated charge may be approximated by the following equation:

Q=(V_{low}−V_{high})×C_{xy} (1)

Q is the transferred charge from the selected sense electrode, V_{high} is the drive-line driver 114 high-output value during Phase 1, e.g., V_{cc}, and V_{low}, is the drive-line driver 114 low value during Phase 2, e.g., ground, and C_{xy} is the capacitance of the selected one of capacitive nodes. Using the result of equation (1), the output voltage Vₒᵤₜ of the integrator circuit may be approximated by the following equation, where Cᵢₙₜ is the capacitance of the integration capacitor:

$${V}_{out} = ( {V}_{low} - {V}_{high} ) \times \frac{{C}_{xy}}{{C}_{int}} \qquad ( 2 )$$

By maintaining the voltage of the selected one of sense lines V(Cp_{y}) at substantially V_{ref}/2 during the beginning of the charge transfer (end of Phase 1) and the end of the charge transfer (end of Phase 2), the effect of parasitic capacitances on the sense lines are cancelled from voltage V(Cp_{y}) transmitted to the integrator. Therefore, change in output voltage V(MUX) during Phase 2 substantially results from charge induced on the sense electrode, only. Any change in voltage V(MUX) from the initial voltage V_{ref}/2 is predominantly a result of the charge induced on the sense electrode. The charge induced on the sense electrode depends on the presence or proximity of an object 122 to be detected. Although this disclosure describes and illustrates a particular change of voltage arising from particular touch sensors, this disclosure contemplates measuring any suitable change of voltage from any device including or excluding touch sensors.

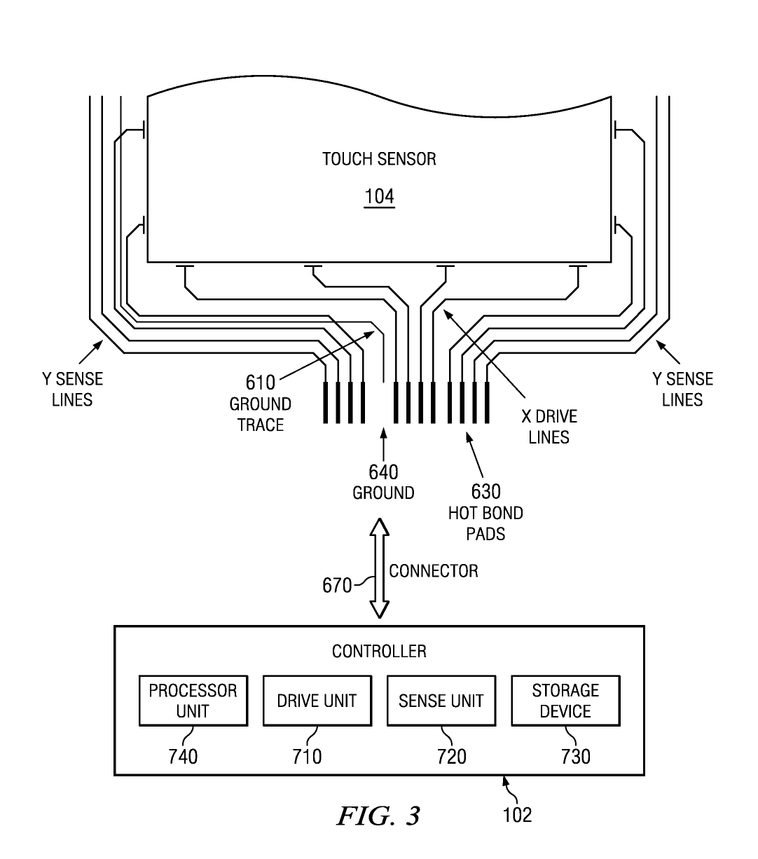

FIG. 3 illustrates an example use of the example system of FIG. 1. In the example of FIG. 3, touch sensor 104 (together with controller 102) may detect the presence and location of a touch by or the proximity of an object within an area of touch sensor 104. Touch sensor 104 may implement a capacitive form of touch sensing. As an example and not by way of limitation, touch sensor 104 may include an array of drive electrodes and sense electrodes forming capacitive nodes. A change in capacitance at a capacitive node of touch sensor 104 may indicate a touch by or the proximity of an object at the position of the node. In a single-layer configuration, the drive and sense electrodes may be disposed in a pattern on one side of a substrate. In such a configuration, a pair of drive and sense electrodes capacitively coupled to each other across a gap between them may form a capacitive node. As an alternative, in a two-layer configuration, the drive electrodes may be disposed in a pattern on one side of a substrate and the sense electrodes may be disposed in a pattern on another side of the substrate. In such a configuration, an intersection of a drive electrode and a sense electrode may form a capacitive node. Such an intersection may be a location where the drive electrode and the sense electrode “cross” or come nearest each other in their respective planes. The drive and sense electrodes do not make electrical contact with each other, instead they are capacitively coupled to each other across the substrate at the intersection. Although this disclosure describes particular configurations of particular electrodes forming particular nodes, this disclosure contemplates any suitable configuration of any suitable electrodes forming any suitable nodes. Moreover, this disclosure contemplates any suitable electrodes disposed on any suitable number of any suitable substrates in any suitable patterns.

Drive electrodes of touch sensor 104 may be coupled to drive lines X, and sense electrodes of touch sensor 104 may be coupled to sense lines Y. Drive lines X and sense lines Y may be coupled to a controller 102 by bond pads 630 on the substrate with touch sensor 104 and by connector 670, which may be wires in a flexible printed circuit (FPC) that controller 102 is on. Bond pads 630 may be bonded using an anisotropic conductive film (ACF). In addition to drive lines X and sense lines Y, there may be a ground trace 610 having an associated ground connector 640. Drive lines X and sense lines Y terminate at bond pads 630.

Controller 102 (which may be a microcontroller) may detect and process the presence and location of a touch by or the proximity of an object within an area of touch sensor 104. As described above, a change in capacitance at a capacitive node of touch sensor 104 may indicate a touch or proximity input at the position of the capacitive. Controller 102 may detect and process the change in capacitance to determine the presence and location of the touch or proximity input. Controller 102 may then communicate information about the touch or proximity input to one or more other components (such one or more central processing units (CPUs) or digital signal processors (DSPs)) of a device (such as a smartphone, a PDA, a tablet computer, a laptop computer, a desktop computer, a kiosk computer, a satellite navigation device, a portable media player, a portable game console, a point-of-sale device, another suitable device, a suitable combination of two or more of these, or a suitable portion of one or more of these), which may respond to the touch or proximity input by initiating a function of the system (or an application running on the device) associated with it. Although this disclosure describes a particular controller having particular functionality with respect to particular devices and particular touch sensors, this disclosure contemplates any suitable controller having any suitable functionality with respect to any suitable device and any suitable touch sensor.

Controller 102 may be one or more ICs, such as for example general-purpose microprocessors, microcontrollers, programmable logic devices or arrays, or ASICs. Controller 102 may include a processor unit 740, a drive unit 710, a sense unit 720, and a storage unit 730. Drive unit 710 may include drivers to communicate drive signals to the drive electrodes of touch sensor 104. Sense unit 720 may sense charge at the capacitive nodes of touch sensor 104 (formed as described above by intersections of drive and sense electrodes or by pairs of drive and sense electrodes capacitively coupled to each other) and provide measurement signals to processor unit 740 representing capacitances at the capacitive nodes. Sense unit 720 may include a parasitic-canceling circuit, as described above. Processor unit 740 may control the communication of drive signals to the drive electrodes by drive unit 710 and process measurement signals from sense unit 720 to detect and process the presence and location of a touch or proximity input on touch sensor 104. Processor unit 740 may also track changes in the position of a touch or proximity input on touch sensor 104. Storage unit 730 may store programming for execution by processor unit 740, including programming for controlling drive unit 710 to communicate drive signals to the drive electrodes, programming for processing measurement signals from sense unit 720, and other suitable programming, where appropriate. Although this disclosure describes a particular controller 102 having a particular implementation with particular components, this disclosure contemplates any suitable controller 102 having any suitable implementation with any suitable components.

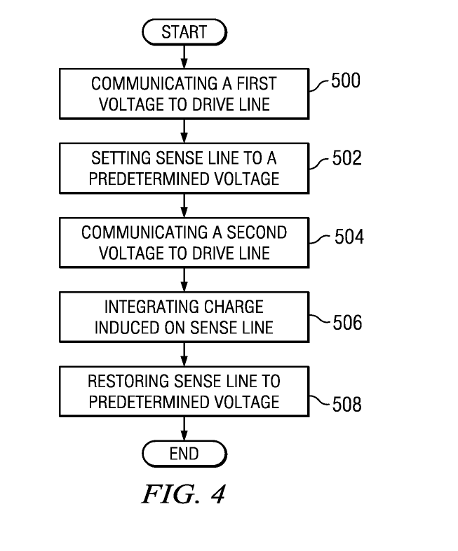

FIG. 4 illustrates an example method for canceling parasitic capacitance in a sensor interface. The method may start at step 500, where a first voltage is communicated to a drive line. In particular embodiments, the first voltage may be generated by a drive unit as illustrated in FIG. 3. At step 502, a sense line may be set to a predetermined voltage. In particular embodiments, the predetermined voltage may be provided by power supply coupled to a negative input terminal of an operational amplifier as illustrated in FIG. 1. At step 504, a second voltage is communicated to the drive line. In particular embodiments, the second voltage may be a logic low, as illustrated in FIG. 2. In particular embodiments, communicating the second voltage to the drive line may induce charge on a corresponding sense electrode resulting in a voltage drop on the sense line, as illustrated in FIG. 2.

At step 506, charge induced on the sense electrode is integrated. In particular embodiments, the charge induced on the sense electrode may be integrated by a capacitor coupled between the negative input terminal and the output terminal of an operational amplifier, as illustrated in FIG. 1. In particular embodiments, the integrated charge may be measured as a voltage difference between the predetermined voltage and the voltage after integrating the induced charge. At step 508, the voltage of the sense line may be restored to the predetermined voltage, at which point the method may end. In particular embodiments, a voltage proportional to the integrated charge may undergo further processing, such as thresholding. Although this disclosure describes and illustrates particular steps of the method of FIG. 4 as occurring in a particular order, this disclosure contemplates any suitable steps of the method of FIG. 4 occurring in any suitable order. Moreover, although this disclosure describes and illustrates particular components carrying out particular steps of the method of FIG. 4, this disclosure contemplates any suitable combination of any suitable components carrying out any suitable steps of the method of FIG. 4.

Herein, reference to a computer-readable storage medium encompasses one or more non-transitory, tangible computer-readable storage media possessing structure. As an example and not by way of limitation, a computer-readable storage medium may include a semiconductor-based or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. Herein, reference to a computer-readable storage medium excludes any medium that is not eligible for patent protection under 35 U.S.C. §101. Herein, reference to a computer-readable storage medium excludes transitory forms of signal transmission (such as a propagating electrical or electromagnetic signal per se) to the extent that they are not eligible for patent protection under 35 U.S.C. §101. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A method comprising:
communicating a first voltage to a drive line of a touch sensor;
setting a sense line of the touch sensor to a predetermined voltage;
communicating a second voltage to the drive line, a resulting transition at the drive line from the first voltage to the second voltage causing an amount of charge accumulated on the sense line to be communicated to an integrator;
at the integrator, integrating the amount of charge communicated from the sense line to convert the amount of charge to an output voltage; and
restoring the sense line to the predetermined voltage.

2. The method of claim 1, wherein restoring the sense line to the predetermined voltage comprises communicating current to the sense line through the integrator.

3. The method of claim 1, further comprising selecting the sense line from a plurality of sense lines.

4. The method of claim 1, wherein integrating the amount of charge comprises coupling an integration capacitor of the integrator between a negative terminal and an output terminal of an operational amplifier.

5. The method of claim 1, wherein the predetermined voltage is half of a reference voltage.

6. The method of claim 1, further comprising removing charge from the integrator by bypassing an integration capacitor of the integrator.

7. The method of claim 1, further comprising:
communicating the output voltage to an analog-to-digital converter; and
converting the output voltage to a digital representation.

8. A circuit configured to:
communicate a first voltage to a drive line of a touch sensor;
set a sense line of the touch sensor to a predetermined voltage;
communicate a second voltage to the drive line, a resulting transition at the drive line from the first voltage to the second voltage causing an amount of charge accumulated on the sense line to be communicated to an integrator;
at the integrator, integrate the amount of charge communicated from the sense line to convert the amount of charge to an output voltage; and
restore the sense line to the predetermined voltage.

9. The circuit of claim 8, wherein the circuit is further configured to communicate current to the sense line through the integrator.

10. The circuit of claim 8, wherein the circuit is further configured to select the sense line from a plurality of sense lines.

11. The circuit of claim 8, wherein the circuit is further configured to couple an integration capacitor of the integrator between a negative terminal and an output terminal of an operational amplifier.

12. The circuit of claim 8, wherein the circuit is further configured to remove charge from the integrator by bypassing an integration capacitor of the integrator.

13. The circuit of claim 8, wherein the circuit is further configured to:
communicate the output voltage to an analog-to-digital converter; and
convert the output voltage to a digital representation.

14. An apparatus comprising:
a touch sensor; and
one or more computer-readable non-transitory storage media coupled to the touch sensor that embody logic that is operable when executed to:
communicate a first voltage to a drive line of the touch sensor;
set the sense line of the touch sensor to a predetermined voltage;
communicate a second voltage to the drive line, a resulting transition at the drive line from the first voltage to the second voltage causing an amount of charge accumulated on the sense line to be communicated to an integrator;
at the integrator, integrate the amount of charge communicated from the sense line to convert the amount of charge to an output voltage; and
restore the sense line to the predetermined voltage.

15. The apparatus of claim 14, wherein the logic is further configured to communicate current to the sense line through the integrator.

16. The apparatus of claim 14, wherein the logic is further configured to select the sense line from a plurality of sense lines.

17. The apparatus of claim 14, wherein the logic is further configured to couple an integration capacitor of the integrator between a negative terminal and an output terminal of an operational amplifier.

18. The apparatus of claim 14, wherein the logic is further configured to remove charge from the integrator by bypassing an integration capacitor of the integrator.

19. The apparatus of claim 14, wherein the logic is further configured to:
communicate the output voltage to an analog-to-digital converter; and
convert the output voltage to a digital representation.

20. The apparatus of claim 14, wherein the predetermined voltage is half of a reference voltage.
